(19) United States
(12) Patent Application Publication
(10) Pub. No.: US 2025/0274121 A1
(43) Pub. Date: Aug. 28, 2025

(54) ISOLATED DRIVER AND AN ISOLATED DRIVING METHOD FOR DRIVING A POWER SWITCHING DEVICE

(71) Applicant: Chengdu Monolithic Power Systems Co., Ltd., Chengdu (CN)

(72) Inventors: Naixing Kuang, Hangzhou (CN); Wei Xu, San Jose, CA (US); Di Han, San Jose, CA (US); Zhijun Ye, Hangzhou (CN)

(21) Appl. No.: 19/065,826

(22) Filed: Feb. 27, 2025

(30) Foreign Application Priority Data
Feb. 28, 2024 (CN) 202410225856.2

(51) Int. Cl. H03K 17/691; H02M 1/08; H03K 17/687

(52) U.S. Cl. CPC H03K 17/691; H02M 1/08; H03K 17/6871; H03K 2217/0081

(57) ABSTRACT

An isolated driver includes a transformer, a primary circuit, a secondary circuit and a driving circuit. In response to an input control signal, the primary circuit provides a primary signal at a primary winding of the transformer, including a first set of primary pulse signals corresponding to a first state of the input control signal and a second set of primary pulse signals corresponding to a second state of the input control signal. The secondary circuit is coupled to a secondary winding of the transformer to receive a secondary signal on the secondary winding and provide an output control signal and an output voltage. In response to the secondary signal, the secondary circuit controls the output control signal to switch between a first state and a second state. The driving circuit provides a driving signal according to the output control signal. The output voltage supplies power to the driving circuit.

### CROSS-REFERENCE

The present application claims priority to, and the benefit of, Chinese application No. 202410225856.2 filed on Feb. 28, 2024, which is incorporated herein by reference in its entirety.

### TECHNICAL FIELD

The present application relates to electronic circuits, and more specifically, the present application relates to isolated drivers and isolated driving methods.

### BACKGROUND

In high-power applications, a power switching device usually needs to withstand high power levels (for example, from several kilowatts to hundreds of kilowatts). However, the control circuit thereof has a lower power level than the power switching device, and its voltage needs to be kept below a safe voltage level. Therefore, a control signal output from the control circuit needs to be electrically isolated when it is transmitted to a control terminal of the power switching device. In the existing technology, the power switching device needs a driving circuit with a certain power level to control its on and off. Therefore, it is necessary to design a reliable isolated driving circuit to realize isolated driving of the power switching device.

### SUMMARY

Therefore, the purpose of the present application is to solve the above technical problems, and to provide an isolated driver and an isolated driving method for driving a power switching device.

According to an embodiment of the present application, the present application provides an isolated driver for driving a power switching device. The isolated driver includes a voltage input terminal, a control input terminal, a transformer, a primary circuit, a secondary circuit and a driving circuit. The voltage input terminal is configured to receive an input voltage. The control input terminal is configured to receive an input control signal. The transformer includes a primary winding and a secondary winding. The primary circuit is coupled to the voltage input terminal and the primary winding and provides a primary signal at the primary winding. The primary signal includes a first set of primary pulse signals and a second set of primary pulse signals. The primary circuit is configured to provide the first set of primary pulse signals at the primary winding in response to the input control signal in a first input control state and provide the second set of primary pulse signals at the primary winding in response to the input control signal in a second input control state. The pulse widths or duty cycles of the second set of primary pulse signals are different from those of the first set of primary pulse signals. The transformer is configured to provide a secondary signal on the secondary winding according to the primary signal, and the secondary signal includes a first set of secondary pulse signals corresponding to the first set of primary pulse signals and a second set of secondary pulse signals corresponding to the second set of primary pulse signals. The secondary circuit is coupled to the secondary winding to receive the secondary signal and configured to provide an output control signal and an output voltage. The secondary circuit is configured to control the output control signal to switch between a first output control state and a second output control state in response to the secondary signal. The driving circuit includes an input terminal and an output terminal. The input terminal of the driving circuit is configured to receive the output control signal, and the output terminal of the driving circuit is configured to provide a driving signal to drive the power switching device according to the output control signal. The driving circuit is powered by the output voltage provided by the secondary circuit.

According to an embodiment of the present application, the present application further provides an isolated driver for driving a power switching device. The isolated driver includes a voltage input terminal, a control input terminal, a transformer, a primary switch circuit, an encoding circuit, a secondary switch circuit, and a decoding circuit. The voltage input terminal is configured to receive an input voltage. The control input terminal is configured to receive an input control signal. The transformer includes a primary winding and a secondary winding. The primary switch circuit includes an upper switch and a lower switch. A first terminal of the upper switch is coupled to the voltage input terminal, a second terminal of the upper switch and a first terminal of the lower switch are coupled to a first terminal of the primary winding, and a second terminal of the lower switch is coupled to a primary reference ground. The encoding circuit is configured to provide a first switching control signal and a second switching control signal according to the input control signal. The first switching control signal is used for controlling the upper switch to turn on and turn off, and the second switching control signal is used for controlling the lower switch to turn on and turn off, so as to provide a primary signal at the first terminal of the primary winding. The transformer is configured to provide a secondary signal at the secondary winding according to the primary signal. The secondary switch circuit is coupled to the secondary winding and is configured to rectify the secondary signal to provide an output voltage. A decoding circuit is configured to provide an output control signal according to the secondary signal for controlling the power switching device to turn on and turn off.

According to an embodiment of the present application, the present application further provides an isolated driving method for driving a power switching device. The isolated driving method includes the following steps: receiving an input voltage and an input control signal; controlling at least one switch in a primary switch circuit to turn on and turn off according to the input control signal, where the primary switch circuit is coupled to a primary winding of a transformer, the primary switch circuit is configured to receive an input voltage and provides a primary signal at the primary winding, and the secondary winding of the transformer is induced by the primary signal to provide a secondary signal; providing an output voltage by rectifying the secondary signal, where the output voltage is used for providing power for driving the power switching device; and providing an output control signal according to the secondary signal, where the output control signal is used for controlling the power switching device to turn on and turn off; where in response to a first input control state of the input control signal, the at least one switch in the primary switch circuit is controlled to be turned on and off in a first sequence to provide the primary signal with first characteristics, and in response to a second input control state of the input control signal, the at least one switch in the primary switch circuit is controlled to be turned on and off in a second sequence to provide the primary signal with second characteristics.

The embodiments of the present application realize the isolated transmission of power while electrically isolating the output control signal from the input control signal.

### BRIEF DESCRIPTION OF DRAWINGS

In order to better understand the present application, the present application will be described in detail according to the following figures.

FIG. 1 is a schematic circuit structure diagram of an isolated driver 100, according to an embodiment of the present application.

FIG. 2 is a timing diagram 200 of the isolated driver 100 shown in FIG. 1, according to an embodiment of the present application.

FIG. 3 is a waveform diagram 300 of the isolated driver 100 shown in FIG. 1, according to another embodiment of the present application.

FIG. 4 is a waveform diagram 400 of the isolated driver 100 shown in FIG. 1, according to another embodiment of the present application.

FIG. 5 is a schematic circuit structure diagram of an isolated driver 500, according to an embodiment of the present application.

FIG. 6 is a schematic circuit structure diagram of the encoding circuit 113, according to

an embodiment of the present application.

FIG. 7 is a schematic circuit structure diagram of the decoding circuit 123, according to an embodiment of the present application.

FIG. 8A is a waveform diagram 800A of the isolated driver 500 shown in FIG. 5, according to an embodiment of the present application.

FIG. 8B is a waveform diagram 800B of the isolated driver 500 shown in FIG. 5, according to another embodiment of the present application.

FIG. 8C is a waveform diagram 800C of the isolated driver 500 shown in FIG. 5, according to yet another embodiment of the present application.

FIG. 9 is a flowchart of an isolated driving method 900, according to an embodiment of the present application.

In the drawings, the same or corresponding reference numerals are used to indicate the same or corresponding elements.

### DETAILED DESCRIPTION

Hereinafter, specific embodiments of the present application will be described in detail, and it should be noted that the embodiments described here are only for illustration and are not used to limit the present application. In the following description, some specific details are included to provide a thorough understanding of embodiments. One skilled in the relevant art will identify, however, that the present application can be practiced without one or more specific details. In other instances, well-known structures, materials, processes or operations are not shown or described in detail to avoid obscuring aspects of the present application.

Throughout the specification and claims, the phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

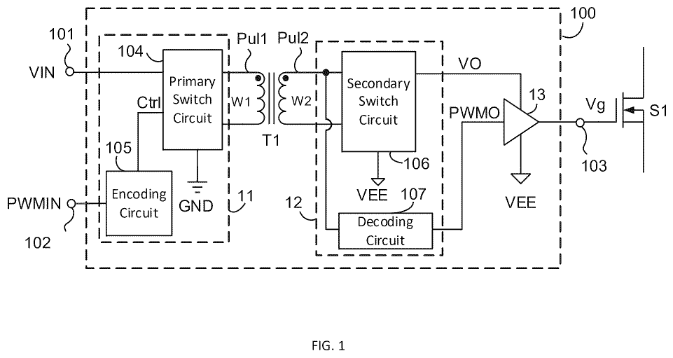

FIG. 1 is a schematic circuit structure diagram of an isolated driver 100, according to an embodiment of the present application. The isolated driver 100 receives an input voltage VIN at a voltage input terminal 101, receives an input control signal PWMIN at a control input terminal 102, and provides a driving signal Vg at an output terminal 103 to drive a power switching device S1. The isolated driver 100 includes a transformer T1, a primary circuit 11, a secondary circuit 12, and a driving circuit 13. The power switching device S1 includes, but is not limited to, metal-oxide-semiconductor field-effect transistor (MOSFET), insulated gate bipolar transistor (IGBT), junction field effect transistor (JFET), high electron mobility transistor (HEMT) and the like.

The transformer T1 includes a primary winding W1 on the primary side and a secondary winding W2 on the secondary side. The primary circuit 11 is coupled to the voltage input terminal 101 to receive the input voltage VIN and is coupled to the primary winding W1. The primary circuit 11 generates a periodic primary signal Pul1 on the primary winding W1 in response to the input control signal PWMIN. For example, the primary circuit 11 generates a first set of first primary pulse signals in response to a first input control state (e.g., high level) of the input control signal PWMIN, and generates a second set of primary pulse signals in response to a second input control state (e.g., low level) of the input control signal PWMIN. In one embodiment, the duty cycles or pulse widths of the first set of primary pulse signals are different from those of the second set of primary pulse signals. The transformer T1 provides a periodic secondary signal Pul2 at the secondary winding W2 according to the primary signal Pul1. A period of the secondary signal Pul2 is the same as that of the primary signal Pul1. In one embodiment, the secondary signal Pul2 includes a first set of secondary pulse signals corresponding to the first set of primary pulse signals and a second set of secondary pulse signals corresponding to the second set of primary pulse signals. The characteristics of the first set of primary pulse signals are different from those of the second set of primary pulse signals, and accordingly the characteristics of the first set of secondary pulse signals are different from those of the second set of secondary pulse signals, so that the first input control state and the second input control state of the input control signal PWMIN can be identified according to the first set of secondary pulse signals and the second set of secondary pulse signals, thereby controlling an output control signal PWMO to switch between a first output control state (e.g., high level) and a second output control state (e.g., low level).

In one embodiment, the isolated driver 100 controls the power switching device S1 to turn on according to the first input control state of the input control signal PWMIN and controls the power switching device S1 to turn off according to the second input control state of the input control signal PWMIN. The secondary circuit 12 is coupled to the secondary winding W2, receives the secondary signal Pul2 provided by the secondary winding W2, and provides the output control signal PWMO and an output voltage VO. An input terminal of the driving circuit 13 receives the output control signal PWMO, and an output terminal of the driving circuit 13 provides the driving signal Vg to drive the power switching device S1 according to the output control signal PWMO. The driving circuit 13 is powered by the output voltage VO provided by the secondary circuit 12. The secondary circuit 12 controls the output control signal PWMO to switch between the first output control state and the second output control state in response to the secondary signal Pul2.

According to an embodiment of the present application, different primary signals Pul1 are provided at the primary side of the transformer T1 according to different states of the input control signal PWMIN, and the secondary signal Pul2 are provided at the secondary side of the transformer T1. The corresponding output control signal PWMO is generated by identifying the characteristics of the secondary signal Pul2. The output control signal PWMO and the input control signal PWMIN are electrically isolated, and the isolated transmission of power is realized to supply power to the driving circuit 13 located at the secondary side of the transformer T1, without an additional power supply circuit, thus simplifying the circuit, saving the area of the circuit board and realizing the isolated driving of the power switching device S1.

In the embodiment shown in FIG. 1, the primary circuit 11 further includes a primary switch circuit 104 and an encoding circuit 105. The primary switch circuit 104 is coupled between the voltage input terminal 101 and the primary winding W1. The encoding circuit 105 provides a switching control signal Ctrl according to the input control signal PWMIN, to control at least one switch in the primary switch circuit 104 to turn on and turn off, thereby generating the primary signal Pul1 at the primary winding W1. In one embodiment, when the input control signal PWMIN is changed to the first input control state, the switching control signal Ctrl controls the at least one switch in the primary switch circuit 104 to turn on at a first duty cycle, and when the input control signal PWMIN is changed to the second input control state, the switching control signal Ctrl controls the at least one switch in the primary switch circuit 104 to turn on at a second duty cycle, which is not equal to the first duty cycle.

In the embodiment shown in FIG. 1, the secondary circuit 12 further includes a secondary switch circuit 106 and a decoding circuit 107. The secondary switch circuit 106 is coupled to the secondary winding W2, and rectifies the secondary signal Pul2 to provide the output voltage VO. The decoding circuit 107 provides the output control signal PWMO according to the secondary signal Pul2. The decoding circuit 107 controls the output control signal PWMO to switch between the first output control state and the second output control state according to the different characteristics of the secondary signal Pul2. In one embodiment, when the decoding circuit 107 identifies the first set of secondary pulse signals, the output control signal PWMO is changed to the first output control state, and when the decoding circuit 107 identifies the second set of secondary pulse signals, the output control signal is changed to the second output control state. In one embodiment, the decoding circuit 107 controls the output control signal PWMO to switch between the first output control state and the second output control state according to the duty cycle of the secondary signal Pul2.

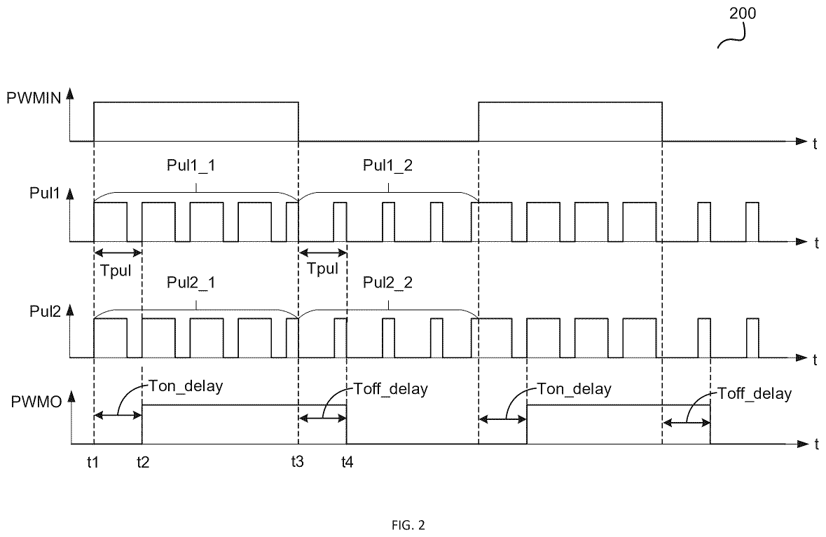

FIG. 2 is a timing diagram 200 of the isolated driver 100, according to an embodiment of the present application. The timing diagram shown in FIG. 2 shows, from top to bottom, the input control signal PWMIN, the primary signal Pul1, the secondary signal Pul2, and the output control signal PWMO.

At time t1, the input control signal PWMIN is changed to high level, and the primary switch circuit 104 provides a first set of primary pulse signals Pul1_1. In the embodiment shown in FIG. 2, the characteristics of the first set of primary pulse signals Pul1_1 include, for example, a plurality of periodic pulses with a first duty cycle. In one embodiment, the first duty cycle is greater than 0.5. The duty cycle of the pulse is a ratio of a duration of high level to the pulse period Tpul. The duty cycle of the primary signal Pul1 is indicative of a ratio of on-duration to a switching period of the at least one switch in the primary switch circuit 104. In one embodiment, a voltage level between a high threshold voltage (for example, 2V) and a power supply voltage (for example, 3.3V) is referred to as high level, and a voltage level between a zero voltage (0V) and a low threshold voltage (for example, 1V) is referred to as low level. Correspondingly, the secondary side of the transformer T1 provides a first set of secondary pulse signals Pul2_1, which has the same duty cycle as the first set of primary pulse signals Pul1_1. At time t2, after a pulse period Tpul, the decoding circuit 107 changes the output control signal PWMO to high level according to the characteristics of the first set of secondary pulse signal Pul2_1, for example, according to the duty cycle of the secondary signal Pul2. A turn-on delay time Toff_delay from a time when the input control signal PWMIN is changed to high level to a time when the output control signal PWMO is changed to high level to turn on the power switching device S1 may be, for example, equal to one pulse period Tpul.

At time t3, the input control signal PWMIN is changed to low level, and the primary switch circuit 104 provides the second set of primary pulse signals Pul1_2. In the embodiment shown in FIG. 2, the characteristics of the second set of primary pulse signals Pul1_2 include, for example, a plurality of periodic pulses with a second duty cycle different from the first duty cycle. In one embodiment, the second duty cycle is less than 0.5. Correspondingly, the secondary side of the transformer T1 provides a second set of secondary pulse signals Pul2_2, which has the same duty cycle as the second set of primary pulse signals Pul1_2. At time t4, after one pulse period Tpul, the decoding circuit 107 changes the output control signal PWMO to low level according to the characteristics of the second set of secondary pulse signals Pul2_2, for example, according to the duty cycle of the secondary signal Pul2. A turn-off delay time Toff_delay from a time when the input control signal PWMIN is changed to low level to a time when the output control signal PWMO is changed to low level to turn off the power switching device S1 may be, for example, equal to one pulse period Tpul.

In another embodiment, the different characteristics of the first set of primary pulse signals Pul1_1 and the second set of primary pulse signals Pul1_2 may also include different pulse widths, i.e., the pulse widths of the first set of secondary pulse signals Pul2_1 are different from those of the second set of secondary pulse signals Pul2_2. The decoding circuit 107 restores the state of the input control signal PWMIN by identifying the different pulse widths of the secondary signal Pul2, so as to generate the output control signal PWMO.

In one embodiment, when the input control signal PWMIN is switched to high level, the primary switch circuit 104 controls the primary signal Pul1 to change to high level and starts to output the first set of primary pulse signals Pul1_1 with first characteristics, and when the input control signal PWMIN is switched to low level, the primary switch circuit 104 controls the primary signal Pul1 to change to low level and starts to output the second set of primary pulse signals Pul1_2 with second characteristics. When detecting the secondary signal Pul2 with the first characteristics, the decoding circuit 107 changes the output control signal PWMO to high level at a rising edge of the secondary signal Pul2, and when detecting the secondary signal Pul2 with the second characteristics, the decoding circuit 107 changes the output control signal PWMO to low level at a falling edge of the secondary signal Pul2.

In the embodiment shown in FIG. 2, the first set of primary pulse signals Pul1_1 has a first duty cycle which, for example, equals to 0.75, and the second set of primary pulse signals Pul1_2 has a second duty cycle which, for example, equals to 0.25. However, those skilled in the art can understand that after the decoding circuit 107 changes the state of the output control signal PWMO according to the duty cycle of the secondary signal Pul2, the duty cycle of the primary signal Pul1 may be changed, for example, the duty cycle of the first set of primary pulse signals Pul1_1 may not be limited to the first duty cycle, and the duty cycle of the second set of primary pulse signals Pul1_2 may not be limited to the second duty cycle.

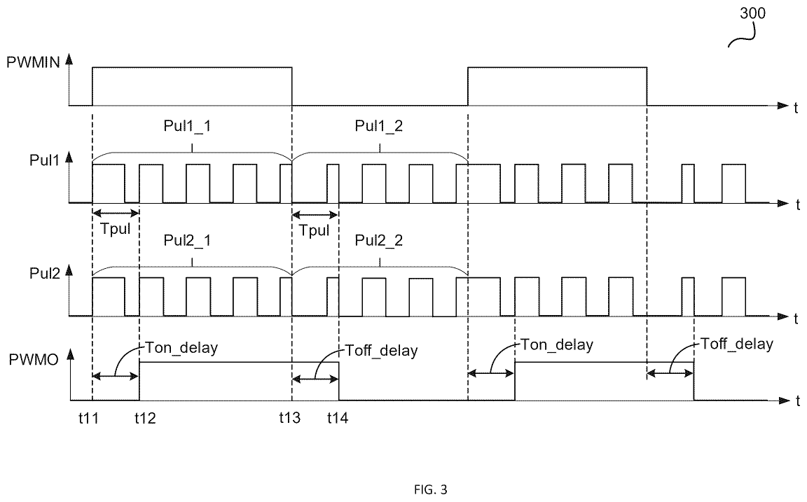

FIG. 3 is a waveform diagram 300 of the isolated driver 100, according to another embodiment of the present application. The waveform diagram shown in FIG. 3 includes, from top to bottom, the input control signal PWMIN, the primary signal Pul1, the secondary signal Pul2, and the output control signal PWMO. In one embodiment, when the input control signal PWMIN is changed to high level, the primary signal Pull and the secondary signal Pul2 have a first duty cycle for at least one pulse period Tpul, and when the input control signal PWMIN is changed to low level, the primary signal Pull and the secondary signal Pul2 have a second duty cycle different from the first duty cycle for at least one pulse period Tpul. In the embodiment shown in FIG. 3, at time t11, the input control signal PWMIN is changed to high level, and the primary switch circuit 104 provides a first set of primary pulse signals Pul1_1 with the first duty cycle. At time t12, the decoding circuit 107 changes the output control signal PWMO to high level according to the duty cycle of the first set of secondary pulse signals Pul2_1. After time t12, the duty cycles of the first set of primary pulse signals Pul1_1 and the first set of secondary pulse signals Pul2_1 are not limited to the first duty cycle, for example, their duty cycles may be equal to 0.5. At time t13, the input control signal PWMIN is changed to low level, and the primary switch circuit 104 provides a second set of primary pulse signals Pul1_2 with the second duty cycle. At time t14, the decoding circuit 107 changes the output control signal PWMO to low level according to the duty cycle of the second set of secondary pulse signals Pul2_2. After time t14, the duty cycles of the second set of primary pulse signals Pul1_2 and the second set of secondary pulse signals Pul2_2 are not limited to the second duty cycle, for example, their duty cycles may be equal to 0.5.

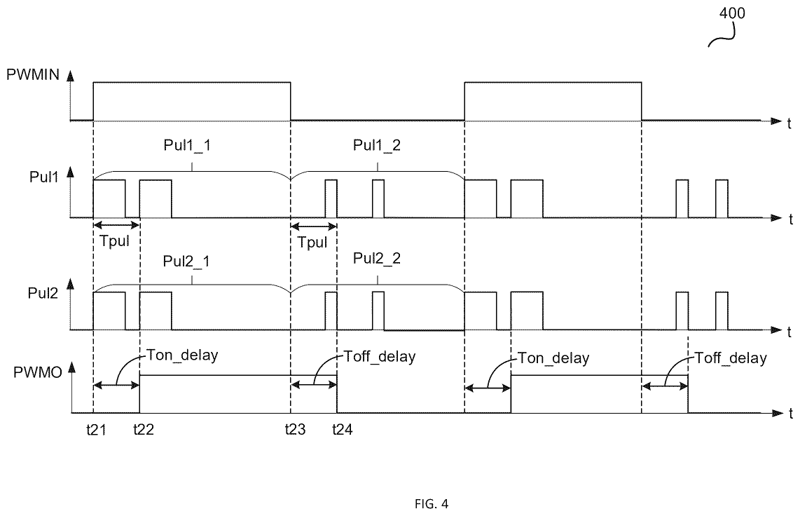

FIG. 4 is a waveform diagram 400 of the isolated driver 100, according to another embodiment of the present application. The waveform diagram shown in FIG. 4 includes, from top to bottom, the input control signal PWMIN, the primary signal Pul1, the secondary signal Pul2, and the output control signal PWMO. In the embodiment shown in FIG. 4, at time t21, the input control signal PWMIN is changed to high level, and the primary switch circuit 104 outputs a first set of primary pulse signals Pul1_1 with a first duty cycle. At time t22, the decoding circuit 107 changes the output control signal PWMO to high level according to the duty cycle of the first set of secondary pulse signals Pul2_1. After time t22, the first set of primary pulse signals Pul1_1 continues to provide one pulse, and then the primary switch circuit 104 stops switching, that is, stops outputting the pulses on the first set of primary pulse signals Pul1_1. At time t23, the input control signal PWMIN is changed to low level, and the primary switch circuit 104 outputs a second set of primary pulse signals Pul1_2 with a second duty cycle. At time t24, the decoding circuit 107 changes the output control signal PWMO to low level according to the duty cycle of the second set of secondary pulse signals Pul2_2. After time t24, the second set of primary pulse signals Pul1_2 continue to provide one pulse, and then the primary switch circuit 104 stops switching, that is, stops outputting the pulses on the second set of primary pulse signals Pul1_2.

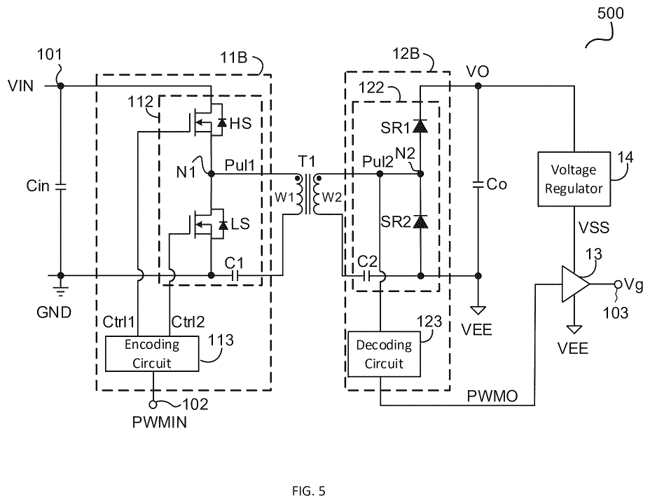

FIG. 5 is a schematic circuit structure diagram of an isolated driver 500, according to an embodiment of the present application. In the embodiment shown in FIG. 5, the primary circuit 11B of the isolated driver 500 includes a primary switch circuit 112. The primary switch circuit 112 includes an upper switch HS and a lower switch LS. A first terminal (e.g., drain) of the upper switch HS is coupled to the voltage input terminal 101 to receive the input voltage VIN. A second terminal (e.g., source) of the upper switch HS and a first terminal (e.g., drain) of the lower switch LS are coupled together to form a common terminal N1 and are coupled to a first terminal of the primary winding W1 to provide the primary signal Pul1. A second terminal (e.g., source) of the lower switch LS is coupled to a primary reference ground GND. An input capacitor Cin is coupled between the voltage input terminal 101 and the primary reference ground GND. In one embodiment, a second terminal of the primary winding W1 is coupled to the primary reference ground GND through a capacitor C1. In one embodiment, the capacitor C1 is used to eliminate DC components of the transformer T1 and prevent the transformer from saturation.

In the embodiment shown in FIG. 5, the primary switch circuit 112 is illustrated as a half-bridge circuit. Those skilled in the art can understand that the primary switch circuit 112 can also adopt other suitable circuit topologies, such as a full-bridge circuit, a flyback circuit, a forward circuit and the like. The upper switch S1 and the lower switch S2 may be, for example, MOSFET, IGBT, JFET, etc. In response to the first input control state of the input control signal PWMIN, the isolated driver 500 controls the upper switch HS and the lower switch LS to be alternately turned on and off in a first sequence to generate the first set of primary pulse signals Pul1_1 with the first characteristics at one terminal of the primary winding W1. In response to the second input control state of the input control signal PWMIN, the isolated driver 500 controls the upper switch HS and the lower switch LS to be alternately turned on and off in a second sequence different from the first sequence to generate the second set of primary pulse signals Pul1_2 with the second characteristics at one terminal of the primary winding W1. Turning on and off the upper switch HS and the lower switch LS alternately in the first sequence includes, for example, controlling the upper switch HS to turn on with the first duty cycle in at least one switching period, and controlling the lower switch LS to turn on complementarily with the upper switch HS in said at least one switching period. Turning on and off the upper switch HS and the lower switch LS alternately in the second sequence includes, for example, controlling the upper switch HS to turn on at the second duty cycle in at least one switching period, and controlling the lower switch LS to turn on complementarily with the upper switch HS in said at least one switching period. In one embodiment, the primary circuit 11B further includes an encoding circuit 113. The encoding circuit 113 receives the input control signal PWMIN, and provides a switching control signal Ctrl1 and a switching control signal Ctrl2 according to the input control signal PWMIN. The switching control signal Ctrl1 is used for controlling the upper switch HS and the switching control signal Ctrl2 is used for controlling the lower switch LS.

The secondary circuit 12B is coupled to the secondary winding W2 and provides an output voltage VO. An output capacitor Co is coupled between the output voltage VO and a secondary reference ground VEE. The secondary winding W2 induces the primary signal Pull on the primary winding W1 to provide the secondary signal Pul2, and the secondary circuit 12B further provides the output control signal PWMO according to the secondary signal Pul2 to control the power switching device to turn on and turn off. The output voltage VO is used to provide power for driving the power switching device. In one embodiment, the secondary circuit 12B includes a secondary switch circuit 122 and a decoding circuit 123. The secondary switch circuit 122 rectifies the secondary signal Pul2 on the secondary winding W2 to provide the output voltage VO. In the embodiment shown in FIG. 5, the secondary switch circuit 122 includes a switch SR1 and a switch SR2. The switch SR1 and the switch SR2 include diodes, for example. A cathode of the switch SR1 is coupled to the output capacitor Co to provide the output voltage and an anode of the switch SR1 and a cathode of the switch SR2 are coupled together to form a common terminal N2, and are coupled to one terminal of the secondary winding W2 to receive the secondary signal Pul2. An anode of the switch SR2 is coupled to the secondary reference ground VEE. The switches SR1 and SR2 are not limited to the diodes shown in FIG. 5, but may be, for example, field effect transistors or transistors. The other terminal of the secondary winding W2 is coupled to the secondary reference ground VEE through a capacitor C2. In one embodiment, the capacitor C2 is used to eliminate the DC components of the transformer T1 and prevent the transformer from saturation. According to the secondary signal Pul2, the decoding circuit 123 restores the input control signal PWMIN at the secondary side of the transformer T1 to provide the corresponding output control signal PWMO. For example, when the secondary signal Pul2 has the first characteristics, the decoding circuit 123 changes the output control signal PWMO to the first output control state, and when the secondary signal Pul2 has the second characteristics, the decoding circuit 123 changes the output control signal PWMO to the second output control state.

In one embodiment, the isolated driver 500 further includes the voltage regulator 14. The voltage regulator 14 receives the output voltage VO, converts the output voltage VO into a power supply voltage VSS, and supplies power to the driving circuit 13. For example, a power supply terminal of the driving circuit 13 is coupled to the voltage regulator 14 to receive the power supply voltage VSS. A reference terminal of the driving circuit 13 is coupled to the secondary reference ground VEE. In one embodiment, the voltage regulator 14 may be, for example, a buck circuit, a buck-boost circuit, a boost circuit, and the like.

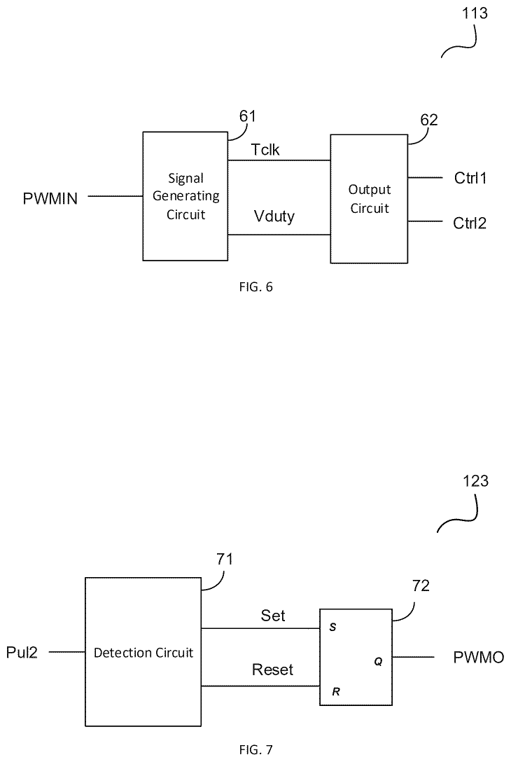

FIG. 6 is a schematic diagram of the circuit structure of the encoding circuit 113, according to an embodiment of the present application. In the embodiment shown in FIG. 6, the encoding circuit 113 includes a signal generating circuit 61 and an output circuit 62. The signal generating circuit 61 receives the input control signal PWMIN and provides a periodic signal Tclk and a duty cycle signal Vduty according to the input control signal PWMIN. The periodic signal Tclk is used to control the switching period of the primary switch circuit 112, and the duty cycle signal Vduty is used to control the duty cycle of the primary signal Pull provided by the primary switch circuit 112. The output circuit 62 provides the switching control signals Ctrl1 and Ctrl2 according to the periodic signal Tclk and the duty cycle signal Vduty. Those skilled in the art can understand that the specific structure of the encoding circuit 113 is not limited to the embodiment shown in FIG. 6.

FIG. 7 is a schematic circuit structure diagram of the decoding circuit 123, according to an embodiment of the present application. In the embodiment shown in FIG. 7, the decoding circuit 123 includes a detection circuit 71 and an RS flip-flop 72. The detection circuit 71 receives the secondary signal Pul2, detects the first input control state and the second input control state of the input control signal PWMIN according to the secondary signal Pul2, and provides a set signal SET and a reset signal RESET according to the detection result. The RS flip-flop 72 provides the output control signal PWMO according to the set signal SET and the reset signal RESET. In one embodiment, when the detection circuit 71 detects that the secondary signal Pul2 has the first characteristics, the set signal SET controls the output control signal PWMO to be set to high level, and when the detection circuit 71 detects that the secondary signal Pul2 has the second characteristics, the reset signal RESET controls the output control signal PWMO to be reset to low level. Those skilled in the art can understand that the specific structure of the decoding circuit 123 is not limited to the embodiment shown in FIG. 7.

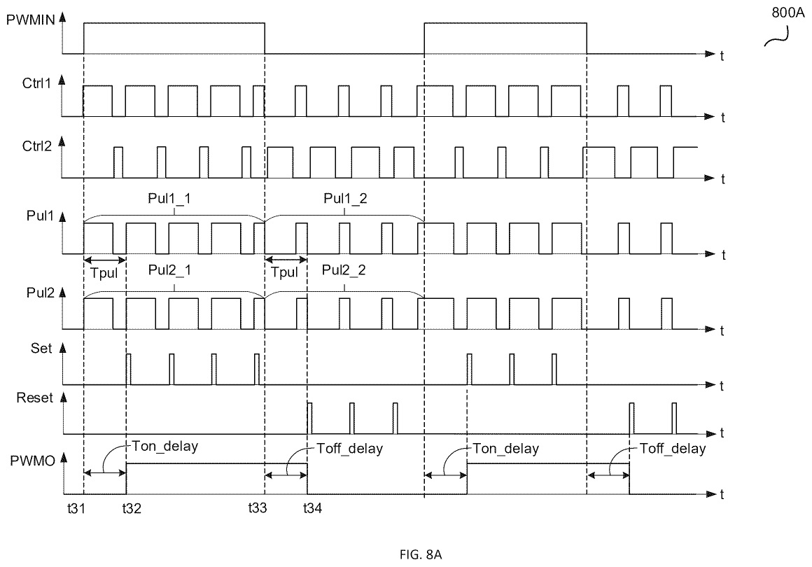

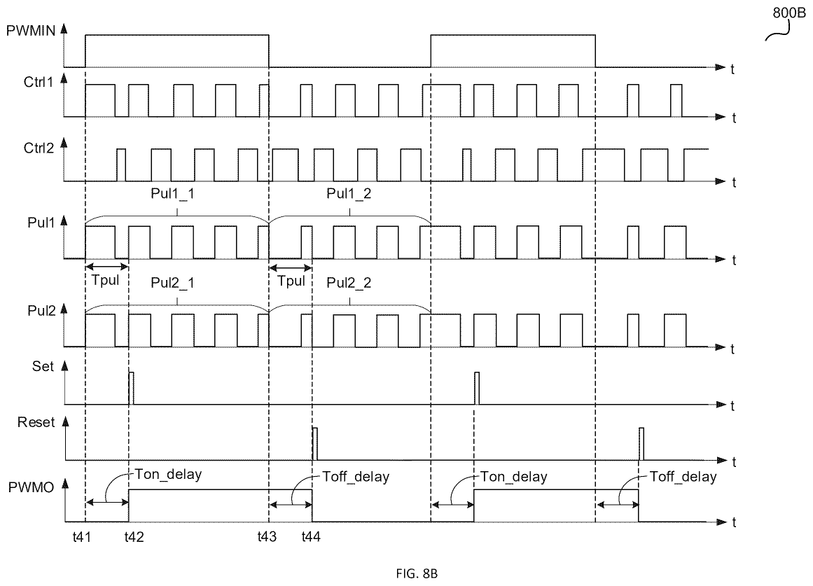

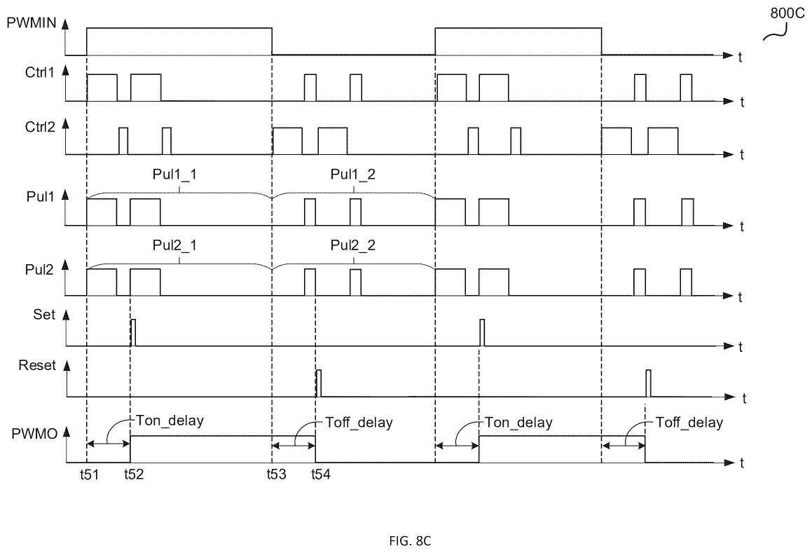

FIG. 8A is a waveform diagram 800A of the isolated driver 500 shown in FIG. 5, according to an embodiment of the present application. The waveform diagram shown in FIG. 8A includes, from top to bottom, the input control signal PWMIN, the switching control signal Ctrl1, the switching control signal Ctrl2, the primary signal Pul1, the secondary signal Pul2, the set signal SET, the reset signal RESET, and the output control signal PWMO.

As shown in FIG. 8A, at time t31, the input control signal PWMIN is changed to high level, the switching control signal Ctrl1 is changed to high level to turn on the upper switch HS, and the switching control signal Ctrl2 remains low level to control the lower switch LS to remain off. The switching control signal Ctrl1 controls the upper switch HS to turn on and turn off periodically with a first duty cycle, and the switching control signal Ctrl2 controls the lower switch LS to turn on and turn off complementarily with the upper switch HS. At time t32, after one switching period, that is, one pulse period Tpul, the decoding circuit 123 detects that the duty cycle of the secondary signal Pul2 conforms to the first characteristics, then the set signal SET is changed to high level to control the output control signal PWMO to high level. At time t33, the input control signal PWMIN is changed to low level, the switching control signal Ctrl1 is changed to low level to control the upper switch HS to turn off, and the switching control signal Ctrl2 is changed to high level to control the lower switch LS to turn on. The switching control signal Ctrl1 controls the upper switch HS to be periodically turned on and off at the second duty cycle, and the switching control signal Ctrl2 controls the lower switch LS to turn on and turn off complementarily with the upper switch HS. After one switching period, that is, one pulse period Tpul, at time t34, the decoding circuit 123 detects that the duty cycle of the secondary signal Pul2 conforms to the second characteristics, and then the reset signal RESET is changed to high level to control the output control signal PWMO to low level.

FIG. 8B is a waveform diagram 800B of the isolated driver 500 shown in FIG. 5, according to another embodiment of the present application. The waveform diagram shown in FIG. 8B includes, from top to bottom, the input control signal PWMIN, the switching control signal Ctrl1, the switching control signal Ctrl2, the primary signal Pul1, the secondary signal Pul2, the set signal SET, the reset signal RESET, and the output control signal PWMO. In the embodiment shown in FIG. 8B, at time t41, the input control signal PWMIN is changed to high level, and the switching control signal Ctrl1 controls the duty cycle of the upper switch HS to be greater than 0.5 in at least one switching period. At time t42, the decoding circuit 123 identifies the high-level input control signal PWMIN according to the secondary signal Pul2, and then the set signal SET is changed to high level to control the output control signal PWMO to high level. Afterwards, the duty cycle of the upper switch HS is not limited to be greater than 0.5, for example, it can be equal to 0.5. At time t43, the input control signal PWMIN is changed to low level, and the switching control signal Ctrl1 controls the duty cycle of the upper switch HS to be less than 0.5 in at least one switching period. At time t44, the decoding circuit 123 identifies the low-level input control signal PWMIN according to the secondary signal Pul2, and the reset signal Reset controls the output control signal PWMO to low level. Afterwards, the duty cycle of the upper switch HS is not limited to less than 0.5, for example, it can be equal to 0.5.

FIG. 8C is a waveform diagram 800C of the isolated driver 500 shown in FIG. 5, according to another embodiment of the present application. The waveform diagram shown in FIG. 8C includes, from top to bottom, the input control signal PWMIN, the switching control signal Ctrrl1, the switching control signal Ctrl2, the primary signal Pul1, the secondary signal Pul2, the set signal SET, the reset signal RESET, and the output control signal PWMO. In the embodiment shown in FIG. 8C, at time t51, the input control signal PWMIN is changed to high level, and the switching control signal Ctrl1 controls the duty cycle of the upper switch HS to be greater than 0.5 in at least one switching period. At time t52, the decoding circuit 123 identifies the high-level input control signal PWMIN according to the secondary signal Pul2, and the set signal SET is changed to high level to control the output control signal PWMO to high level. Subsequently, after one pulse of the first set of primary pulse signals Pul1_1, the primary switch circuit 112 stops the switching action, so that both the upper switch HS and the lower switch LS remain off, thereby stopping the pulses on the first set of primary pulse signals Pul1_1. At time t53, the input control signal PWMIN is changed to low level, and the switching control signal Ctrl1 controls the duty cycle of the upper switch HS to be less than 0.5 in at least one switching period. At time t54, the decoding circuit 107 identifies the low-level input control signal PWMIN according to the secondary signal Pul2, and the reset signal Reset is changed to high level to control the output control signal PWMO to low level. Subsequently, after one pulse of the second set of primary pulse signals Pul1_2, the primary switch circuit 112 stops the switching action, so that both the upper switch HS and the lower switch LS remain off, thereby stopping the pulses on the second set of primary pulse signals Pul1_2.

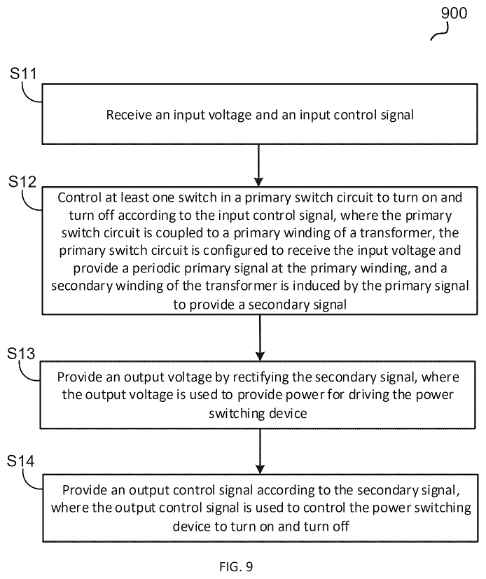

FIG. 9 is a flowchart of an isolated driving method 900, according to an embodiment of the present application. The isolated driving method 900 includes steps S11 to S14. Step S11: receiving an input voltage and an input control signal. Step S12, controlling at least one switch in a primary switch circuit to turn on and turn off according to the input control signal, where the primary switch circuit is coupled to a primary winding of a transformer, the primary switch circuit is configured to receive the input voltage and provide a periodic primary signal at the primary winding, and a secondary winding of the transformer is induced by the primary signal to provide a secondary signal. Step S13, providing an output voltage by rectifying the secondary signal, where the output voltage is used to provide power for driving a power switching device. Step S14, providing an output control signal according to the secondary signal, where the output control signal is used to control the power switching device to turn on and turn off.

In one embodiment, the method further includes controlling the at least one switch in the primary switch circuit to turn on and turn off in a first sequence in response to a first input control state of the input control signal. For example, the at least one switch is controlled to be turned on in a first duty cycle in at least one switching period to provide the primary signal with first characteristics, and in response to a second input control state of the input control signal, the at least one switch in the primary switch circuit is controlled to be turned on and off in a second sequence, for example, the at least one switch is controlled to be turned on in a second duty cycle in at least one switching period to provide the primary signal with second characteristics.

In one embodiment, the output control signal controls the power switching device to turn on in response to the input control signal changing to the first input control state, and the output control signal controls the power switching device to turn off in response to the input control signal changing to the second input control state, and the switching period is a switching period of the primary switch circuit.

In one embodiment, providing the output control signal according to the secondary signal includes: in response to the first characteristics of the secondary signal, controlling the output control signal to switch to a first output control state to control the power switching device to turn on, and in response to the second characteristics of the secondary signal, controlling the output control signal to switch to a second output control state to control the power switching device to turn off.

Although the present application has been described with reference to several exemplary embodiments, it should be understood that the terminology used is illustrative and exemplary rather than limiting. As the present application can be embodied in various forms without departing from the spirit or essence of the present application, it should be understood that the above-mentioned embodiments are not limited to any of the foregoing details, but should be broadly interpreted within the spirit and scope defined by the appended claims, and therefore all changes and modifications that fall within the scope of the claims or their equivalents are intended to be covered by the appended claims.

1. An isolated driver for driving a power switching device, comprising:
a voltage input terminal, configured to receive an input voltage;
a control input terminal, configured to receive an input control signal;
a transformer, comprising a primary winding and a secondary winding;
a primary circuit, coupled to the voltage input terminal and the primary winding, and configured to provide a primary signal at the primary winding, wherein the primary signal comprises a first set of primary pulse signals and a second set of primary pulse signals, and wherein the primary circuit is configured to provide the first set of primary pulse signals at the primary winding in response to the input control signal in a first input control state and provide the second set of primary pulse signals at the primary winding in response to the input control signal in a second input control state, pulse widths or duty cycles of the second set of primary pulse signals are different from that of the first set of primary pulse signals; and wherein
the transformer is configured to provide a secondary signal on the secondary winding according to the primary signal, and the secondary signal comprises a first set of secondary pulse signals corresponding to the first set of primary pulse signals and a second set of secondary pulse signals corresponding to the second set of primary pulse signals;
a secondary circuit, coupled to the secondary winding to receive the secondary signal and configured to provide an output control signal and an output voltage, wherein the secondary circuit is configured to control the output control signal to switch between a first output control state and a second output control state in response to the secondary signal; and
a driving circuit, comprising an input terminal and an output terminal, wherein the input terminal of the driving circuit is configured to receive the output control signal, and the output terminal of the driving circuit is configured to provide a driving signal to drive the power switching device according to the output control signal, and the driving circuit is powered by the output voltage provided by the secondary circuit.

2. The isolated driver according to claim 1, wherein the primary circuit comprises:
a primary switch circuit, coupled between the voltage input terminal and the primary winding, wherein the primary switch circuit comprises at least one switch; and
an encoding circuit, configured to provide a switching control signal according to the input control signal to control the at least one switch in the primary switch circuit to turn on and turn off, thereby generating the primary signal at the primary winding.

3. The isolated driver according to claim 2, wherein the switching control signal is configured to control the at least one switch in the primary switch circuit to turn on at a first duty cycle when the input control signal is changed to the first input control state, and the switching control signal is configured to control the at least one switch in the primary switch circuit to turn on at a second duty cycle when the input control signal is changed to the second input control state, wherein the first duty cycle is not equal to the second duty cycle.

4. The isolated driver according to claim 1, wherein the secondary circuit comprises:
a secondary switch circuit, coupled to the secondary winding, and configured to rectify the secondary signal to provide the output voltage; and
a decoding circuit, configured to provide the output control signal according to the secondary signal, wherein the output control signal is changed to the first output control state when the decoding circuit identifies the first set of secondary pulse signals, and is changed to the second output control state when the decoding circuit identifies the second set of secondary pulse signals.

5. The isolated driver according to claim 1, wherein the secondary circuit comprises:
a secondary switch circuit, coupled between the secondary winding and the output voltage, and configured to rectify the secondary signal to provide the output voltage; and
a decoding circuit, configured to provide the output control signal according to the secondary signal, wherein the decoding circuit controls the output control signal to switch between the first output control state and the second output control state according to the duty cycle of the secondary signal.

6. The isolated driver according to claim 1, wherein the primary circuit comprises:
a primary switch circuit, comprising an upper switch and a lower switch, wherein a first terminal of the upper switch is coupled to the voltage input terminal, a second terminal of the upper switch and a first terminal of the lower switch are coupled to a first terminal of the primary winding, and a second terminal of the lower switch is coupled to a primary reference ground; and
an encoding circuit, configured to provide a first switching control signal and a second switching control signal according to the input control signal, wherein the first switching control signal is used for controlling the upper switch and the second switching control signal is used for controlling the lower switch, so as to provide the primary signal at the first terminal of the primary winding.

7. The isolated driver according to claim 6, wherein a second terminal of the primary winding is coupled to the primary reference ground through a first capacitor.

8. The isolated driver according to claim 6, wherein when the input control signal is changed to the first input control state, the upper switch is turned on at least in one switching period with a first duty cycle, and when the input control signal is changed to the second input control state, the upper switch is turned on at least in one switching period with a second duty cycle, wherein the second duty cycle is not equal to the first duty cycle.

9. The isolated driver according to claim 1, wherein the secondary circuit comprises:
a secondary switch circuit, comprising a first switch and a second switch, wherein a first terminal of the first switch is coupled to an output capacitor to provide the output voltage, a second terminal of the first switch and a first terminal of the second switch are coupled to a first terminal of the secondary winding, and a second terminal of the second switch is coupled to a secondary reference ground; and
a decoding circuit, configured to provide the output control signal according to the secondary signal.

10. The isolated driver according to claim 9, wherein a second terminal of the secondary winding is coupled to the secondary reference ground through a second capacitor.

11. An isolated driver for driving a power switching device, comprising:
a voltage input terminal, configured to receive an input voltage;
a control input terminal, configured to receive an input control signal;
a transformer, comprising a primary winding and a secondary winding;
a primary switch circuit, comprising an upper switch and a lower switch, wherein a first terminal of the upper switch is coupled to the voltage input terminal, a second terminal of the upper switch and a first terminal of the lower switch are coupled to a first terminal of the primary winding, and a second terminal of the lower switch is coupled to a primary reference ground;
an encoding circuit, configured to provide a first switching control signal and a second switching control signal according to the input control signal, wherein the first switching control signal is used for controlling the upper switch to turn on and turn off, and the second switching control signal is used for controlling the lower switch to turn on and turn off, so as to provide a primary signal at the first terminal of the primary winding, wherein the transformer is configured to provide a secondary signal at the secondary winding according to the primary signal;
a secondary switch circuit, coupled to the secondary winding, and configured to rectify the secondary signal to provide an output voltage; and
a decoding circuit, configured to provide an output control signal according to the secondary signal for controlling the power switching device to turn on and turn off.

12. The isolated driver according to claim 11, wherein a second terminal of the primary winding is coupled to the primary reference ground through a first capacitor.

13. The isolated driver according to claim 11, wherein the secondary switch circuit comprises a first switch and a second switch, a first terminal of the first switch is coupled to an output capacitor to provide the output voltage, a second terminal of the first switch and a first terminal of the second switch are coupled to a first terminal of the secondary winding, and a second terminal of the second switch is coupled to a secondary reference ground.

14. The isolated driver according to claim 13, wherein a second terminal of the secondary winding is coupled to the secondary reference ground through a second capacitor.

15. The isolated driver according to claim 11, wherein when the input control signal is changed to a first input control state, the upper switch is turned on at least in one switching period with a first duty cycle, and when the input control signal is changed to a second input control state, the upper switch is turned on at least in one switching period with a second duty cycle, wherein the second duty cycle is not equal to the first duty cycle.

16. The isolated driver according to claim 15, wherein the output control signal is configured to control the power switching device to turn on or turn off in response to the state of the input control signal.

17. The isolated driver according to claim 11, wherein the decoding circuit is configured to control the output control signal to switch between a first output control state and a second output control state according to the duty cycle of the secondary signal.

18. An isolated driving method for driving a power switching device, comprising:
receiving an input voltage and an input control signal;
controlling at least one switch in a primary switch circuit to turn on and turn off according to the input control signal, wherein the primary switch circuit is coupled to a primary winding of a transformer, and the primary switch circuit is configured to receive the input voltage and provide a primary signal at the primary winding, and wherein a secondary winding of the transformer is induced by the primary signal to provide a secondary signal;
providing an output voltage by rectifying the secondary signal, wherein the output voltage is used for providing power for driving the power switching device; and
providing an output control signal according to the secondary signal, wherein the output control signal is used for controlling the power switching device to turn on and turn off; wherein in response to a first input control state of the input control signal, the at least one switch in the primary switch circuit is controlled to be turned on and off in a first sequence, to provide the primary signal with first characteristics, and in response to a second input control state of the input control signal, the at least one switch in the primary switch circuit is controlled to be turned on and off in a second sequence to provide the primary signal with second characteristics.

19. The isolated driving method according to claim 18, wherein the output control signal controls the power switching device to turn on in response to the input control signal changing to the first input control state, and the output control signal controls the power switching device to turn off in response to the input control signal changing to the second input control state, and the switching period is a switching period of the primary switch circuit.

20. The isolated driving method according to claim 18, wherein providing the output control signal according to the secondary signal comprises:
in response to the first characteristics of the secondary signal, controlling the output control signal to switch to a first output control state to control the power switching device to turn on; and
in response to the second characteristics of the secondary signal, controlling the output control signal to switch to the second output control state to control the power switching device to turn off.
